(19) United States
(12) Patent Application Publication
(10) Pub. No.: US 2010/0266766 A1
(43) Pub. Date: Oct. 21, 2010

(54) GUIDING DEVICES AND METHODS FOR CONTACTLESS GUIDING OF A WEB IN A WEB COATING PROCESS

(76) Inventors: Stefan Hein, Blankenbach (DE); Andre Herzog, Alzenau (DE); Peter Skuk, Nidderau (DE); John D. Busch, Oberursel (DE)

Correspondence Address: PATTERSON & SHERIDAN, L.L.P., 3040 POST OAK BOULEVARD, SUITE 1500, HOUSTON, TX, 77056, US

(21) Appl. No.: 12/427,453

(22) Filed: Apr. 21, 2009

(51) Int. Cl. C23C 14/00; C23C 14/56

(52) U.S. Cl. 427/255.5; 118/50; 118/729

(57) ABSTRACT

According to embodiments described herein, a guiding device for contactless guiding of a web in a web coating process under vacuum conditions is provided. The guiding device includes a curved surface for facing the web and a group of gas outlets disposed in the curved surface and adapted for giving off a gas flow to form a hover cushion between the curved surface and the web. The guiding device further includes a gas distribution system for selectively providing the gas flow to a first subgroup of the gas outlets and for preventing the gas from flowing to a second subgroup of the gas outlets.

### FIELD OF THE INVENTION

Embodiments of the invention generally relate to guiding devices in web coating processes and to methods of guiding webs in web coating processes. In particular, embodiments relate to devices and methods for contactless web guiding by means of hover cushions. Some embodiments relate to devices and methods for web guiding in thin-film solar cell production, others to web guiding in the production of flexible displays.

### BACKGROUND OF THE INVENTION

In apparatuses and methods for coating a web such as in the production of thin-film solar cells it is necessary to guide the web. This may be due to the fact that the moving direction of the web has to be changed. Another possible application of guiding the web is where the front side of the web is coated and the rear side of the web has to be backed. For these examples and other applications it is known to provide rollers and drums that allow for changing the moving direction of the web and/or backing the web.

However, in many applications, in particular in thin-film solar cell production applications, the direct contact of a coated web with rollers on the side of the web that is already coated may harm the coating. As a result, the coating apparatuses have been designed such that the contact of the rollers with the web is exclusively on the rear side of the web. As described herein, the term “rear side of the web” relates to the side of the web that is not coated, while “front side of the web” relates to the side of the web that is coated. Due to these design limitations complex moving paths have had to be designed within the coating apparatuses and/or the overall path length of coating apparatuses is substantially limited.

To avoid contact of the front side of the web with a roller, a hover cushion may be formed between the roller and the web. Therein, a gas is emitted from gas outlets in the surface of the roller, and the web, even if its front side faces the roller, does not contact the roller but hovers on a cushion of the emitted gas. However, in typical applications, the coating process takes place under vacuum conditions. The emitted gas for the hover cushion may be detrimental to the vacuum conditions and/or strain a vacuum pump system. Besides, the gas may be expensive and be wasted in the process.

### SUMMARY OF THE INVENTION

In light of the above, a guiding device, a coating apparatus, a method for contactless guiding of a web, and a method for coating a web as described herein are provided.

According to embodiments described herein, a guiding device for contactless guiding of a web in a web coating process application under vacuum conditions is provided. The guiding device includes a curved surface for facing the web and a group of gas outlets disposed in the curved surface and adapted for giving off a gas flow to form a hover cushion between the curved surface and the web. The guiding device further includes a gas distribution system for selectively providing the gas flow to a first subgroup of the gas outlets and for preventing the gas from flowing to a second subgroup of the gas outlets.

According to other embodiments described herein, an apparatus for coating a web including a guiding device according to embodiments described herein is provided. The apparatus for coating the web further includes a coating tool.

According to further embodiments described herein, a method for contactless guiding of a web in a web coating process under vacuum conditions is provided. The method includes moving the web over a curved surface in a web guiding region of the curved surface, wherein gas outlets are disposed in the curved surface which are adapted for giving off a gas to form a hover cushion between the curved surface and the web. The method further includes emitting a flow of the gas from the curved surface through a first subgroup of the gas outlets in the web guiding region for generating the hover cushion between the curved surface and the web and preventing the gas from flowing through a second subgroup of the gas outlets outside of the web guiding region.

According to other embodiments described herein, a method for coating a web is provided that includes a method for contactless guiding of a web according to embodiments described herein. The method for coating the web further includes coating the web.

Further advantages, features, aspects and details that can be combined with the above embodiments are evident from the dependent claims, the description and the drawings.

Embodiments are also directed to apparatuses for carrying out each of the disclosed methods and including apparatus parts for performing each described method steps. These method steps may be performed by way of hardware components, a computer programmed by appropriate software, by any combination of the two or in any other manner. Furthermore, embodiments are also directed to methods by which the described apparatus operates or by which the described apparatus is manufactured. It includes method steps for carrying out functions of the apparatus or manufacturing parts of the apparatus.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C show schematic views of a guiding device according to embodiments described herein.

FIGS. 2A-2D show cross-sectional views of a guiding device according to embodiments described herein.

FIGS. 3A-3B show cross-sectional views of sector chambers of a guiding device according to embodiments described herein.

FIGS. 3C-3D show perspective views of sector chambers of a guiding device according to embodiments described herein.

FIGS. 4A-4B show planarized views of surfaces of a guiding device according to embodiments described herein.

FIGS. 5A-5C show cross-sectional views of a guiding device according to embodiments described herein.

FIGS. 6A-6C show planarized views of surfaces of a guiding device according to embodiments described herein.

FIG. 7 shows a schematic view of a coating apparatus including guiding devices according to embodiments described herein.

### DETAILED DESCRIPTION

Within the following description of the drawings, the same reference numbers refer to the same components. Generally, only the differences with respect to the individual embodiments are described. The drawings are not necessarily true to scale and serve for illustration.

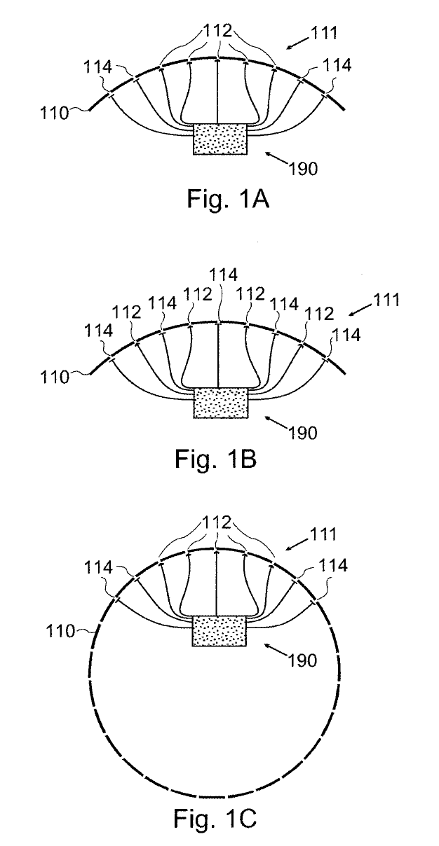

FIGS. 1A to 1C are schematic views symbolically illustrating embodiments of the guiding device for guiding a web. Note that “guiding a web” as described herein particularly includes changing the web's moving direction. “Guiding a web” may include backing the web. The guiding device can be adapted for use in a web coating process application, e.g. chemical vapor deposition (CVD) or plasma enhanced chemical vapor deposition (PECVD). The guiding device can, e.g., be used in industrial production of flexible photovoltaic webs, flexible electronics, flexible displays, high barrier coatings, and packaging material processing.

Such production processes are typically carried out under vacuum conditions. As opposed to, e.g., paper processing in printing applications typically conducted under atmospheric pressure, processing of a web under vacuum conditions poses additional technical challenges. While process gases may need to be locally introduced into a vacuum chamber, the vacuum must be maintained with a good quality, e.g., to avoid transfer of one process gas to another processing section where it may be detrimental to processing. Any gas that is introduced into the vacuum chamber without serving processing and/or guiding the web, merely adds to the load on the vacuum system such as pumps.

As shown in FIGS. 1A to 1C, the guiding device includes a curved surface 110 for facing a web. Typically, as shown in FIG. 1C, the curved surface is rotationally symmetric, e.g. cylindrical. In the surface 110, gas outlets 111 are disposed, which are adapted to give off a gas. The term “facing” in this context refers to the situation that the surface of the guiding device is positioned and oriented such that the web moves slightly above the surface when the guiding device is in operation. Therein, the side of the web facing the surface can be the front side of the web or the back side.

The gas forms a hover cushion for the web when the device is in operation. The hover cushion may be formed between the surface and the web, typically such that the web is contactless with respect to the surface. According to many embodiments described herein, the hover cushion is such that there is no friction between web and surface. Typically, according to many embodiments described herein, the hover cushion generated is capable of carrying the web on the cushion. According to some embodiments described herein, the web can be arranged such that the coated side of the web faces the surface of the guiding device. Although the coated side, i.e. the front side, may face the surface, the coated side does typically not have any direct contact with the surface.

According to embodiments described herein, the guiding device includes a gas distribution system 190. The gas is supplied from the gas distribution system 190. The gas distribution system 190 can provide the gas selectively to a first subgroup 112 of the gas outlets 111. In FIGS. 1A to 1C, the first subgroup 112 of gas outlets 111, to which the gas is provided, is illustrated by supply lines ending in an arrow. Further, the gas distribution system 190 can prevent the gas from flowing to a second subgroup 114 of the gas outlets 111, typically the rest of the gas outlets 111. In FIGS. 1A to 1C, the second subgroup 114 of gas outlets 111, to which no gas is provided, is illustrated by supply lines ending in a bar.

The term “subgroup” as used herein refers to non-empty, proper subset of the gas outlets in the mathematical sense. Typically, the union of the first and the second subgroup equals the whole group of gas outlets. In other words, if the first subgroup is given, the second subgroup consists of the remainder of the gas outlets. Generally, during operation, the membership of any single gas outlet to the first or second subgroup may change. In other words, an open gas outlet may be closed at a later time and vice versa.

The gas distribution system may be connected to a main gas supply or gas reservoir (not shown), e.g. by a pipe or the like. The gas distribution system can be subdivided into sections. Each section can be provided with a different gas pressure or even a different gas from the main gas supply. The gas distribution system may include at least one pressure adjuster. According to other embodiments, the at least one pressure adjuster is replaced by at least one mass flow controller. Typically, the at least one pressure adjuster or the at least one mass flow controller are not part of the guiding device but can be provided externally.

According to embodiments which can be combined with any other embodiments described herein, a curved surface can be rotationally symmetric surface. Typically, the curved surface is rotationally symmetric around an axis. In particular, the curved surface may be selected from a group consisting of a cylindrical surface, a concave-cylindrical surface, a surface of a cone, and a surface of a truncated cone. Therein, the term “concave-cylindrical” refers to a rotationally symmetric surface which has a concave profile in a depth direction D along the symmetry axis. The concave profile may e.g. be hyperbolic. In some embodiments, the curved surface is rotatable, typically around the symmetry axis. More particularly, the curved surface can be rotationally symmetric with respect to an axis and be rotatable around this axis. According to embodiments which can be combined with any other embodiments described herein, the curved surface may be heatable, coolable and/or biasable with a voltage.

In some embodiments, the curved surface is the surface of a roller. A roller as referred to herein is an object which is rotationally symmetric around a rotation axis. The roller may be cylindrical, e.g. a drum, or be concave-cylindrical. The roller may also be a cone or a truncated cone. Typically, the roller is rotatable around the rotation axis.

In other embodiments, the curved surface can be a convex surface, e.g. an arc. In some embodiments, the curved surface is non-rotatable. The convex surface can be elongate, e.g. elliptical or a segment of an ellipse. Such a convex surface may be used in coating applications where the coating path length is preferably long.

According to embodiments which can be combined with any other embodiments described herein, any individual gas outlet, any subgroup of the gas outlets or all gas outlets can be selected from the group consisting of: openings, holes, slits, nozzles, blast pipes, spray valves, duct openings, orifices, jets, and the like. According to typical embodiments, the outlets are recesses in the surface that are typically funnel-shaped or cup-shaped with the recesses being fed with gas from the bottom of the recesses or sideways. The gas outlets of the guiding device described herein can also be openings of a porous layer. Typically, the gas outlets do not protrude out of the surface.

The gas outlets may individually or collectively be equipped with valves and a valve control system. The valves can be open by default, in other words “normally open”. Valves that are open by default provide the gas even in case the control of the valves malfunctions, such that the hover cushion is generated even in such emergency case. In some embodiments, the gas outlets are oriented to provide the gas flow perpendicularly to the surface of the guiding device and/or perpendicularly to the web. In particular, the orientation of the gas outlets can be neutral with respect to any direction of movement of the web, which means that no transport is effected by the orientation of the gas outlets.

A web as used with the embodiments described herein can typically be characterized in that it is bendable or flexible. The term “web” may be synonymously used to the term “strip”. For instance, the web as described in embodiments herein may be a foil or other synthetic substrate. For example, the web may be selected from a group of substrates consisting of steel substrates, stainless steel substrates, polymer substrates, PET substrates, PEN substrates, and polyamide substrates. According to some embodiments, which can be combined with any other embodiment described herein, the web has a thickness from 10 μm to 600 μm, more typically from 15 μm to 500 μm, such as 50 μm or 100 μm.

In more detail, during operation, the web moves on a hover cushion that is generated between the surface of the guiding device and the web when the gas is emitted from the first subgroup 112 of the gas outlets 111 disposed in the surface 110 of the guiding device. In typical applications, the pressure of the web against the hover cushion is in the range from 0.1 mbar to 500 mbar, more typically from 10 mbar to 100 mbar such as 50 mbar.

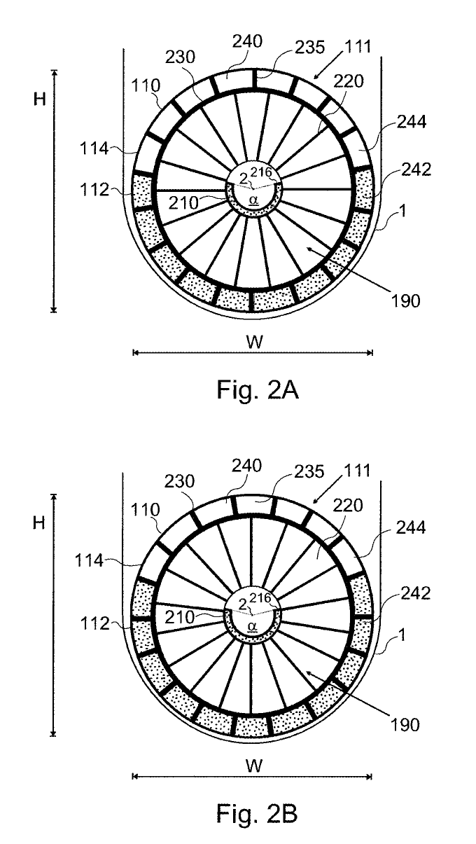

Generally, during operation, the web is guided over a web guiding region on the surface. The web guiding region is defined as the area of the surface from which gas needs to be emitted to avoid contact of the web with the surface of the guiding device. The size of the web guiding region may depend on parameters such as the weight or area density of the web, the tension with which the web is pulled towards the surface, the quantity of the gas flow emitted from the surface, the pattern of active gas outlets in the surface, and attractive or repelling forces such as electrostatic forces, e.g. if the surface is biased with a voltage. The size of the web guiding region strongly depends on the enlacement angle, also called wrap angle, with which the web is wound around the surface. For example, in FIGS. 2A and 2B, the enlacement angle is 180°.

The ability of the gas distribution system to either provide or stop the gas flow to selected gas outlets increases the flexibility of the guiding device. Generally, during operation, the first subgroup of “open” gas outlets 112 may change, i.e., at a different point in time different gas outlets may belong to the first subgroup of gas outlets through which gas is emitted. Likewise, the second subgroup of “closed” gas outlets 114 may change. In other words, membership of the gas outlets to the first and/or second subgroup may change. In some embodiments, the gas distribution system is adapted to change membership of the gas outlets to the first and/or second subgroup in situ, i.e. during the web guiding process.

In typical embodiments, as shown in FIGS. 1A and 1C, the first subgroup 112 of the gas outlets forms a contiguous area on the surface 110. Typically, this contiguous area forms the web guiding region. Outside of the web guiding region, the second subgroup 114 of gas outlets is shut off from gas supply by the gas distribution system. Thereby, waste of possibly expensive gas, e.g. the process gas of a web coating application, may be reduced. Also, in particular, by reducing the waste of gas, a better quality of a vacuum may be maintained and the strain on a vacuum system be reduced.

In some embodiments, membership of the gas outlets to the first and/or second subgroup is changed during operation in dependence of the rotation of the curved surface. Therein, typically, the web guiding region remains at a fixed position in space, and any gas outlet entering the web guiding region by means of the rotation is opened, i.e., its membership is changed to the first subgroup. Any gas outlet leaving the web guiding region by means of the rotation is closed, i.e., its membership is changed to the second subgroup.

According to embodiments, which can be combined with any other embodiments described herein, the gas may be selected from the group consisting of: inert gases, argon, nitrogen, hydrogen, silane and any mixtures thereof. In CVD applications, hydrogen and silane are typically used, in PVD, (i.e., sputter applications) argon and nitrogen are typically used. The gas flow rate for providing the hover cushion may generally be from 0.05 to 50 slmp (1 standard liter per minute equals 1.68875 Pa m³/s), typically from 0.1 to 30 slmp, e.g. 10 or 20 slmp.

In some embodiments, which can be combined with any of the embodiments described herein, web guiding takes place under vacuum conditions. By closing the second subgroup 114 of gas outlets, the quality of the vacuum may be improved and/or the strain on a pump system maintaining the vacuum may be reduced. Vacuum pressures may generally range from 10⁻⁵ to 20 mbar. Vacuum pressure within a vacuum chamber may locally vary. In particular, in a coating area where process gases have to be present, the vacuum pressure may typically range from 10⁻⁴ to 10⁻² mbar in sputter application, e.g. with nitrogen or argon as process gases, and from 1-10 mbar in CVD or PECVD applications, e.g. using hydrogen and/or silane as process gas. Outside of the coating area, vacuum pressures are generally less than the pressures in the coating area. The gradient is typically maintained by a vacuum pump system.

As shown in FIG. 1B, according to some embodiments, the first subgroup 112 and/or second subgroup 114 of gas outlets do not form contiguous regions. In FIG. 1B, open and closed gas outlets alternate in the cross-sectional direction shown. Generally, the gas distribution system may be adapted to control the pattern of open and closed gas outlets, i.e. the pattern formed by the first and/or second subgroup of gas outlets. Thereby, the flexibility of the guiding device may be increased, and waste of gas and/or strain on the vacuum pumps be reduced. The gas distribution system may control and change this pattern in situ, i.e. during operation of the guiding device.

FIGS. 2A, 2B, 2C, and 2D show a guiding device including a rotationally symmetric surface 110. The guiding device is shown in a cross-sectional view and has a width W and a height H. A depth D of the guiding device is oriented perpendicularly to the plane of drawing. Typically, the web guiding device is a cylindrical drum with constant width W and height H. Alternatively, the width W and height H may vary along the depth D, e.g. linearly such that the guiding device is a cone or truncated cone. The cone or truncated cone may, e.g., be used if a lateral off-set in guiding the web is desired, i.e., if the web should be displaced in the direction of the depth D.

In FIGS. 2A to 2D, the first subgroup 112 of the gas outlets, i.e., the open gas outlets 112, lie in the web guiding region. The first subgroup 112 of the gas outlets 111 is overlapped by a web 1. Herein, the term “overlapped” does not imply a contact of the web 1 and the surface 110 because, during operation, the hover cushion is formed between the first subgroup 112 of the gas outlets in the web guiding region and the web. Thereby, generally, a direct contact between the web and the guiding device is avoided.

The second subgroup 114 of the gas outlets, i.e., the closed gas outlets 114, lies outside of the web guiding region. Since gas is only emitted in the web guiding region where it is needed to form the hover cushion, meaning no or little gas is directly emitted into a region not overlapped by the web, waste of gas may be reduced and/or a better vacuum be maintained at lesser strain on the pump system. In particular, if the gas outlets not overlapped by the web were open, an even higher pressure of the gas would be needed to create a hover cushion, thus adding to the waste of gas and/or load on the pump system.

According to some embodiments, as shown in FIGS. 2A to 2D, the gas distribution system 190 is a star distributor. A star distributor will later be described with respect to FIGS. 2A to 2D. Generally, the gas distribution system 190 includes a main gas feed 210 and individual gas outlet feeds 220 in fluid communication with the gas outlets 111. In some embodiments illustrated in FIGS. 2A, 2B and 2C, the gas distribution system 190 may further include sector chambers 240. Sector chambers, which will be described in more detail below, may serve to simplify the construction of the gas distribution system, since the gas need only be provided to each sector chamber, and not necessarily to each individual gas outlet.

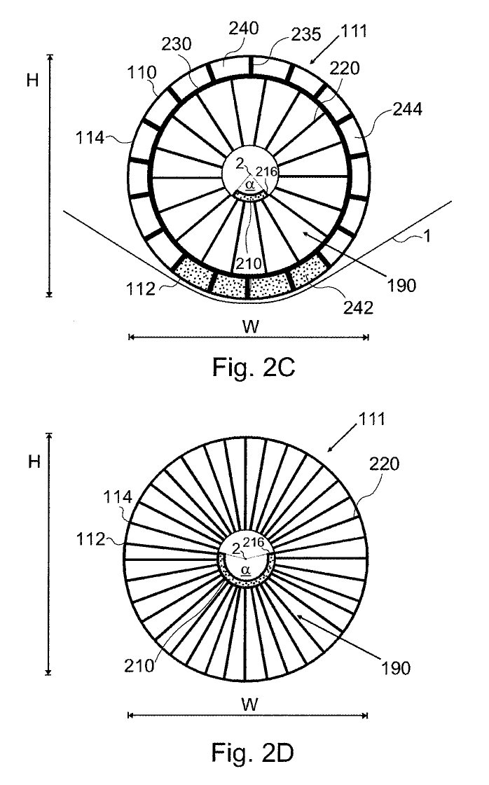

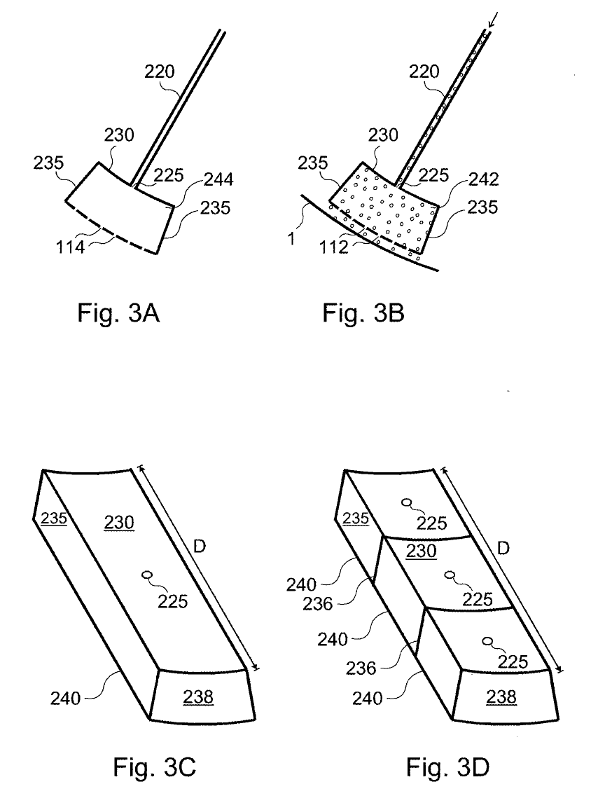

As shown in FIGS. 2A to 2C and FIGS. 3A to 3D, the sector chambers 240 can be formed by a rotationally symmetric inner wall 230, a plurality of radial sector walls 235 and the surface 110. The gas outlet feeds 220 are in fluid communication with the sector chambers 240 through gas inlets 225. The gas outlet feeds 220 are adapted to provide the gas to the sector chambers 240 via gas inlets 225 if the gas outlet feeds 220 are in fluid communication with the main gas feed 210.

FIGS. 2A and 2B show sector chambers 242 in fluid communication with the main gas feed 210 and sector chambers 242 not in fluid communication with the main gas feed 210. FIG. 3A shows a single sector chamber 244 that is not in fluid communication with the main gas feed. The gas outlets 114 of the sector chamber therefore belong to the second subgroup, i.e., they are shut off from gas supply. FIG. 3B, on the other hand, shows a single sector chamber 242 in fluid communication with the main gas feed 210 as indicated by the arrow in the top part of the figure. Therefore, the gas outlets 112 of the sector chamber belong to the first subgroup, i.e. they are supplied with gas. The gas is symbolically illustrated by little circles. During operation, the gas forms the hover cushion between the surface 110 and the web 1.

As shown in FIG. 3C each sector chamber 240 may extend over the whole depth D of the guiding device. In this case, typically only one gas outlet feed 220 is needed to provide fluid communication with the main gas feed 210 via gas inlet 225. Alternatively, as shown in FIG. 3D, a single sector chamber 240 extends over only part of the depth D. In FIG. 3D, three sector chambers 240 are shown aligned along the depth D. Each of these three sector chambers is delimited by the inner wall 230, the surface 110, the radial walls 235, and by azimuthal walls 236 and/or 238. Therein azimuthal walls 238 may be part of the side walls of the guiding device. However, any number of sector chambers in a row along the depth D may be provided, e.g. 2, 3, 4, 5 or more sector chambers. For example, if the sector chambers 240 are subdivided in the depth direction D as shown in FIG. 3D, and the main gas feed 210 is likewise subdivided in this direction, wherein the subdivided sections of the main gas feed 210 may be provided selectively and individually with gas from the main gas supply, a pattern of open and closed gas outlets may be formed in the depth direction D. Also, pressure gradients along the depth direction may be realized and/or different gases be provided to individual sector chambers 240 via individual gas inlets 225.

In other embodiments, as shown in FIG. 2D, the gas outlet feeds 220 are each in fluid communication with a single gas outlet or with a row of gas outlets in the depth direction, instead of with a group of gas outlets defined by the sector chambers 240.

According to some embodiments, the main gas feed 210 is a sector of a rotationally symmetric, typically cylindrical, cavity. The angle α of the sector may be adjustable. The sector angle α can be adjustable in the building of the guiding device, in the set-up of the guiding device, or even in situ, i.e., during operation of the guiding device. For example, the cavity walls 216 defining the sector angle α, which extend into the plane of drawing in FIGS. 2A-2D, may be adjustable.

The sector angle α of the main gas feed typically depends on the enlacement angle of the web. As shown in FIG. 2C, in view of FIGS. 2A and 2B, the enlacement angle of the web 1 may vary, e.g. for different processing applications or for different webs. The sector angle α may be adjusted to the web guiding region, which is different for different enlacement angles. In some embodiments, the sector angle and the enlacement angle are substantially the same. Herein, “substantially the same” means that they may differ by an angle from 0° to 10°. In other embodiments, the sector angle α is chosen larger than the enlacement angle to provide a safety tolerance, e.g. by 5°, 10°, or 15°. Generally, sector angles and/or enlacement angles may range from 10° to 240°, more typically from 30° to 180°, such as 45°, 90°, 135° or 180°.

The gas may be provided from the main gas supply through the cavity walls 216 defining the sector angle and/or through the side walls of the cavity. The side walls of the cavity are the walls delimiting the extension of the cavity in the depth direction D of the guiding device. The side walls further seal the main gas feed 210 in the depth direction D.

According to some embodiments, the curved surface of the guiding device is rotatable. The surface may be a rotationally symmetric surface, for example the rotationally symmetric surface of a roller. In FIGS. 2A, 2B, and 2C, a roller such as a cylindrical drum with a rotational axis 2 is shown in a cross-sectional view. In some embodiments, the sector chambers 240 and the gas outlet feeds 220 are rotatable along with the surface 110. The main gas feed 210, on the other hand, may not be rotatable but stationary.

During operation of the guiding device, different gas outlet feeds 220 become fluidly connected or disconnected from the main gas feed 210. Likewise, the gas outlets in fluid communication with the sector chambers become fluidly connected or disconnected from the main gas feed 210. Hence, membership of the gas outlets to the first subgroup 112 of open gas outlets and to the second subgroup 114 of closed gas outlets can change during operation.

The changing of membership is illustrated in FIGS. 2A and 2B. FIG. 2A shows the guiding device at a first point in time. In FIG. 2A, ten sector chambers 242 are pressurized, i.e. in fluid connection with the main gas feed 210. FIG. 2B shows the same guiding device at a second, later point in time different from the first point in time. Assuming that the guiding device is turned clockwise, FIG. 2B, as compared to FIG. 2A, shows the guiding device turned by an angle of 10°, measured clockwise. Thereby, an eleventh sector chamber 242 on the right has become fluidly connected to the main gas feed 210. At an even later third point in time, when the guiding device is turned clockwise by, e.g., another 10°, the uppermost sector chamber 242 will become disconnected from the main gas feed 210. Likewise, the gas outlets belonging to each sector chamber become pressurized or depressurized, changing their membership to the first and second subgroup of the gas outlets 111. While a clockwise rotation has been described for illustration, a counterclockwise rotation is possible as well.

The curved surface 110 is, according to some embodiments, adapted to be rotated with a surface velocity that is equal to the speed of the web, i.e. the guiding velocity. Such a surface will be called synchronized with the web. Likewise, if the surface is the surface of a roller, the roller is said to be synchronized with the web. Since, in these cases, any part of the web in the web guiding region is substantially stationary with respect to the co-moving surface, large frictional forces that may destroy the web do not occur even if gas distribution should fail and the hover cushion became absent.

In general, according to embodiments which can be combined with any of the embodiments described herein, the moving speed of the web in operation of the guiding device is from 0.1 m/min to 15 m/min, typically from 20 cm/min to 10 m/min. In CVD applications, the speed of the web is even more typically from 50 cm/min to 1 m/min, such as 70 cm/min, whereas in sputter applications the web speed is even more typically in the range from 2 m/min to 10 m/min such as 5 m/min.

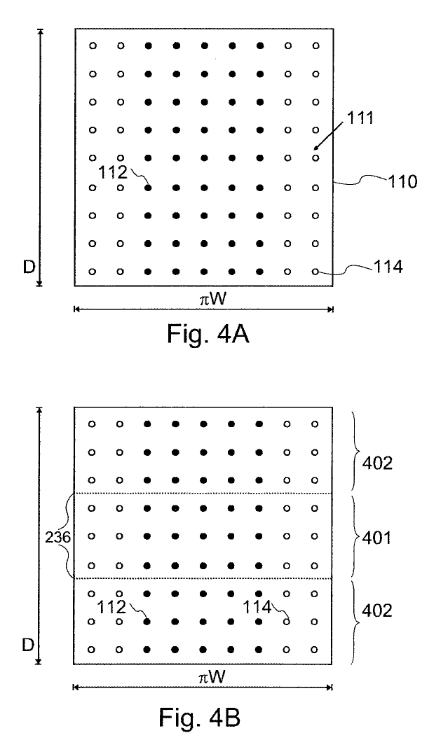

FIGS. 4A and 4B show an unrolled, planarized version of a cylindrical surface 110 of a guiding device. Herein, “unrolled” means that, for the sake of illustration, the surface is depicted as if cut open along the depth direction D and spread out in a plane. The number of gas outlets 111 depicted in the figures is only for illustration and may, e.g., be much higher than shown. The first subgroup 112 of gas outlets is symbolized by filled circles, whereas the second subgroup 114 of gas outlets is symbolized by empty circles. In the examples shown in FIGS. 4A and 4B, the width of the web guiding region as defined by the pressurized gas outlets 112 is five ninth of the circumference □W, corresponding to an angle of 200°.

For instance, FIG. 4A may represent the surface 110 of the guiding device including sector chambers as shown in and described with respect to FIG. 3C. Similarly, FIG. 4B may represent the surface 110 of the guiding device including sector chambers as shown in and described with respect to FIG. 3D. Hence, in FIG. 4B, the azimuthal walls 236 below the surface 110 are indicated by dashed lines. In some embodiments, a pressure gradient of the gas flow is created. For example, the gas outlets in an inner region 401 belonging to a central sector chamber can be provided with gas at a higher pressure than gas outlets in outer regions 402 belonging to respective outer sector chambers.

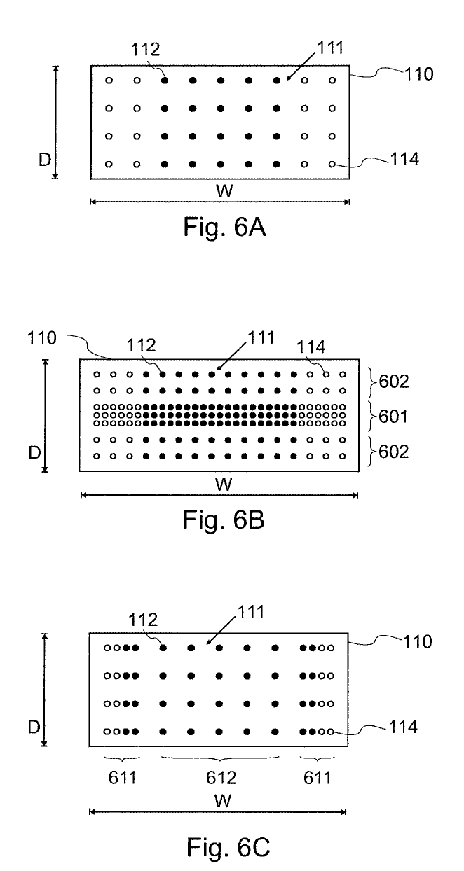

In FIGS. 4A and 4B, the gas outlets 111 are arranged form of an even-spaced matrix. Embodiments with other arrangements of the gas outlets, which can be combined any other embodiments described herein, will be described later with respect to FIGS. 6A to 6C.

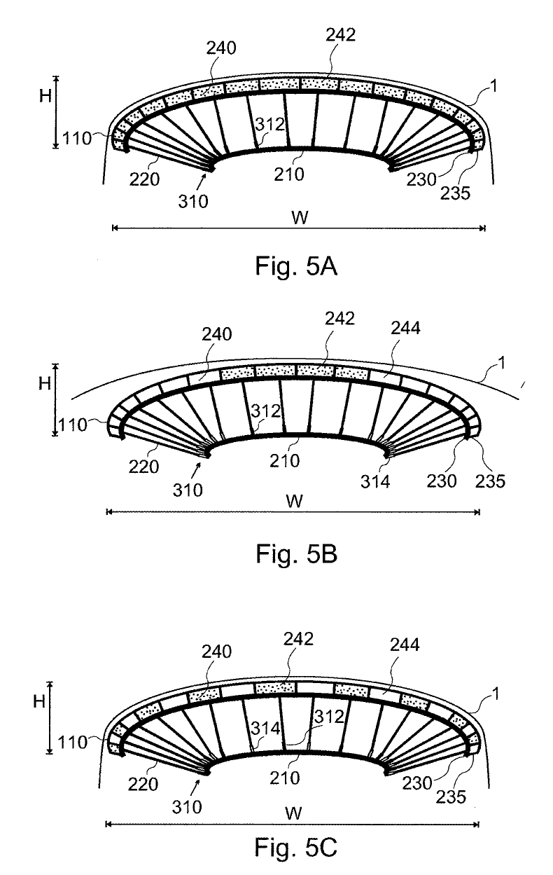

In further embodiments, the surface speed may be different from the speed of the web, in particular, the surface speed may be null. In the latter case, the design of the guiding device may be simpler. In some embodiments described herein, the guiding device surface 110 of the guiding device is non-rotatable or static, i.e. it is not adapted for being rotated. The shape of a non-rotatable surface need not be rotationally symmetric, but may have any shape, e.g. a convex shape. Some embodiments of a guiding device with non-rotatable surface will now be described with respect to FIGS. 5A to 5C.

The surface 110 of the embodiments described with regard to FIGS. 5A, 5B, and 5C is shown as a segment with a partly elliptic cross-section. The term “segment” of a geometrical shape such as a cylinder and/or an oval and/or an ellipse refers to only a portion of the object in the following. The surface 110 illustrated in FIGS. 5A, 5B, and 5C is non-rotatable.

For instance, according to some embodiments which can be combined with any of the embodiments with a non-rotatable surface described herein, the guiding device surface may have an oval or partly oval such as an elliptic or partly elliptic cross-section. In those embodiments, a major axis and a minor axis can be assigned to the surface shape. The length of the major axis may be up to 20 m, more typically up to 15 m, even more typically up to 10 m. The length of the minor axis is typically chosen as below 1.5 m, more typically below 1 m, even more typically below 0.5 m. In view of space requirements it is desirable to maximize the relation between major axis and minor axis. However, in order to guarantee a minimum pressure of the web against the surface (with the generated hover cushion therebetween), the relation between major axis and minor axis is typically limited, e.g. not larger than 20, 15, 10, or 5. As described herein, an ellipse is understood as special case of an oval in accordance with a mathematical understanding of these geometries.

Embodiments of the guiding device illustrated in FIGS. 5A-5C include the main gas feed 210, the individual gas outlet feeds 220, and the sector chambers 240 formed by the surface 110, a wall 230 with partly elliptic cross-section, and separating sector walls 235.

According to embodiments which can be combined with any other embodiments described herein, the guiding device may further include a valve system 310 adapted to control the gas flow to the individual gas outlet feeds 220. In FIGS. 5A-5C, open valves of the valve system are referenced by the number 312, closed valves by the number 314.

In FIG. 5A, all valves are open valves 312 such that all sector chambers are sector chambers 242 in fluid connection with the main gas feed 210. The web guiding region extends over the whole width W of the surface 110, with the web 1 overlapping the whole surface 110. In contrast, in FIG. 5B, the enlacement angle of the web 1 is smaller such that the web guiding region is smaller, too. Here, valves 314 leading to sector chambers 244 outside of the web guiding region are closed. Hence, no gas is wasted through gas outlets not needed to form a hover cushion. If the guiding device is operated under vacuum conditions, the quality of the vacuum may be improved. As illustrated in FIG. 5C, the valve system 310 may be adapted to form any pattern of sector chambers 242 and 244 that are, respectively are not, in fluid communication with the main gas supply 210. Thereby, the flexibility of the guiding device may be increased.

The valves of the valve system may be open by default. Such valves open by default give off gas even if control of the valve fails. Hence, the hover cushion is provided even if the control of the valves fails. In other embodiments, the valves are closed by default. Such valves do not give off gas if control of the valve fails. Thereby, no waste gas is given off in case of control failure, e.g. preventing gas to be transferred to other sections of web processing. Generally, the valves can be electrically or mechanically controllable. The valves can be installed in the gas outlet feeds 220, or in the sector chambers or the gas outlets. Similarly as in FIG. 2D, the individual gas outlet feeds 220 can each also directly feed a single gas outlet or a row of gas outlets in the direction of the depth D, and sector chambers be absent.

FIGS. 6A, 6B and 6C schematically show further embodiments of the surface of the guiding device. The view of FIGS. 6A to 6C is as if the surface was planar. The views may, either be from above or below the guiding device showing the dimensions width W and depth D, or the views may show unrolled, planarized versions of cylindrical surfaces. In the latter case, the width W shown in FIGS. 6A to 6C would have to be replaced by the circumference □W. Aberrations due to perspective effects are suppressed. It will be understood by those skilled in the art that the surfaces shown in FIGS. 6A to 6C can be provided in and combined with all embodiments of the guiding device described herein and in particular in those embodiments having a partly or fully cylindrical or a partly or fully elliptic cross-sectional shape. In particular, the surfaces shown in FIGS. 6A to 6C can be provided in the embodiments described with regard to FIGS. 1A to 5C and 7.

Generally, the width W of the guiding device may be in the range from 5 cm to 20 m, and the height H from 5 cm to 2 m. In embodiments with a cylindrical surface, the range of the width and height H is typically from 5 cm to 2 m, more typically from 10 cm to 140 cm, even more typically from 20 cm to 40 cm, such as 20, 30, or 40 cm. In embodiments with an elliptic surface, the range of the width is typically from 2 to 20 m, more typically from 3 to 12 m, such as 5 or 10 m. The depth D of the guiding device can generally be in the range from 0.1 to 4 m, more typically from 0.5 to 2 m, such as 0.6, 1.0, or 1.4 m.

In some embodiments described herein, the shape of the guiding device surface is cylindrical or partly cylindrical. Hence, it is possible to assign the width W or height H as a diameter to the cylindrical surface. In typical embodiments, the diameter lies between 5 cm and 1 m, more typically between 10 cm and 70 cm, even more typically between 20 cm and 50 cm.

In FIGS. 6A to 6C, gas outlets of the first subgroup 112, i.e., open gas outlets, are depicted as black circles, while the second subgroup 114 of gas outlets is depicted as white circles. The distribution of open and closed gas outlets will be called a pattern. FIGS. 6A and 6B, may be typical arrangements of gas outlets of embodiments described with respect to FIGS. 5A-5C. FIGS. 6A and 6B, may also be typical arrangements of gas outlets of embodiments described with respect to FIGS. 2A-2D, wherein the width W shown in the figures would have to be replaced by the circumference □W. An arrangement as shown in FIG. 5C is more typical for a non-rotatable, in particular not rotationally symmetric surface.

The patterns shown in FIGS. 6A to 6C are only exemplary. Generally, any row of gas outlets in the depth direction D may either be pressurized or shut off from gas supply, e.g. by adjusting the sector angle α of the main gas feed 210 in FIGS. 2A-2C. Also, any row in the width direction W may be open or closed. To this aim, the main gas feed 210 may be subdivided, in the direction D, by cavity walls to form main gas feed chambers. Each subdivided main gas feed chamber may be individually and selectively provided with gas from the main gas supply. Further, e.g., by including valves to the gas outlets or gas outlet feeds 220, any pattern may be realized. The flexibility of the guiding device may be increased, an optimal pressure distribution in the hover cushion be more closely reached, waste of gas reduced, a vacuum be better maintained and/or load on a vacuum system be reduced.

According to the embodiment shown in FIG. 6A, the gas outlets are disposed in a regular manner. The feature “disposed in a regular manner” is to be understood that the distance of an outlet and at least one neighbor outlet of it is identical to the distance of another gas outlet with respect to at least one neighbor of the other gas outlet. More typically, the feature “disposed in a regular manner” refers to a surface wherein a specific pattern can be assigned to a portion of the multitude of outlets and the same pattern can be assigned to another portion of the multitude of outlets, more typically to at least 10 other portions of a multitude of outlets, even more typically to at least 100 portions of the multitude of outlets.

The gas outlets according to the embodiments of FIGS. 6A to 6C are arranged in an array manner. According to many embodiments, the distances between a gas outlet and its next neighbor are identical for all gas outlets. In general, and not limited to the embodiments of FIGS. 6A, 6B and 6C, between 0.5 and 400, typically between 1 and 200, more typically between 60 and 100 gas outlets are provided per 100 cm². In typical embodiments, the distance between the gas outlets is between 5 mm and 500 mm, more typically between 10 mm and 30 mm. Generally, the diameter of the gas outlets is between 0.1 mm and 1 mm, more typically between 0.2 mm and 0.8 mm, even more typically between 0.4 mm and 0.6 mm.

According to typical embodiments of the guiding device described herein, the multitude of gas outlets comprises at least 500 gas outlets, typically at least 1000 gas outlets, even more typically at least 3000 gas outlets.

FIG. 6B illustrates further embodiments of the surface of the guiding device which can be combined with other embodiments described herein. Once again the gas outlets are arranged in a regular manner. Further, the gas outlets are arranged in an array manner. In contrary to the embodiment of FIG. 6A though, the distances between the gas outlets 111 are smaller in the inner region 601 of the surface than they are in the outer region 602 of the surface 110.

Hence, according to typical embodiments described herein that are combinable with all other embodiments, the guiding device comprises a first region having a multitude of gas outlets that are arranged in a more condensed manner than the gas outlets of a second region. In typical embodiments, the first region is arranged in the middle of the surface of the guiding device as seen in the depth direction D. This embodiment may be advantageous because typically a smaller amount of gas has to be introduced in order to generate the gas cushion capable of carrying the web. This is because the gas emitted from the outer region 602 of the surface can more easily flow to the edge of the surface thus not contributing to the generation of the gas cushion anymore.

According to some embodiments described herein, such as the embodiment of FIG. 6B, the distance between the gas outlets in the outer region 602 of the surface is typically at least 1.1 times larger than the distance between the gas outlets in the outer region 602 of the surface, more typically between 1.5 and 3 times larger. The number of gas outlets per area in the inner region 601 of the surface is typically at least 1.1 times larger than the number of gas outlets per area of gas outlets in the outer region 602 of the surface, more typically between 1.5 and 9 times such as between 2.25 and 9 times larger.

The typical depth of the inner region 601 having the gas outlets arranged in a more condensed manner is in the range of between ¼ and ⅔ of the total depth of the surface. In typical embodiments, the depth of the inner region 601 having the gas outlets arranged in a more condensed manner is between 20 and 80 cm, more typically between 30 and 50 cm.

FIG. 6C illustrates further embodiments of the surface of the guiding device. According to those embodiments, the surface comprises a region having the gas outlets arranged in a more condensed manner than the gas outlets of another region. As illustrated in FIG. 6C, the region having the outlets arranged in a more condensed manner may be provided in the edge region 611 of a non-rotatable guiding device surface with respect to its width W. Accordingly, the region having the outlets arranged in a less condensed manner may be provided in the middle region 612 of the guiding device surface with respect to its width W. An arrangement as illustrated with respect to FIG. 6C may be advantageous in those applications where the web needs a stronger support in the edge regions of the non-rotatable guiding device surface with respect to its width. For instance, this may be useful in those embodiments where the slope of the surface is steeper in the edge region 611 of the surface with respect to its width than it is in the middle region 612.

According to some embodiments described herein, such as the embodiment of FIG. 6C, the distance between the gas outlets in the middle region 612 of the surface is typically at least 1.1 times larger than the distance between the gas outlets in the edge region 611 of the surface, more typically between 1.5 and 3 times larger. The number of gas outlets per area in the edge region 611 of the surface is typically at least 1.1 times larger than the number of gas outlets per area of gas outlets in the middle region 612 of the surface, more typically between 1.5 and 9 times such as between 2.25 and 9 times larger.

The typical length of the edge region 611 having the gas outlets arranged in a more condensed manner is in the range of between 1/10 and ¼ of the total length of the surface. In typical embodiments, the length of the edge region 611 having the gas outlets arranged in a more condensed manner is between 5 cm and 30 cm, more typically between 10 and 20 cm.

In embodiments with a non-rotatable surface of the guiding device, typically, the embodiments shown in FIGS. 6B and 6C can be combined. That is, according to some embodiments described herein, the gas outlets on the surface of the guiding device can be arranged in a more condensed manner in both the middle region 601 along the depth direction (as shown in FIG. 6B) and in the edge region 611 along the width direction (as shown in FIG. 6C).

According to further embodiments, which can be combined with any of the embodiments described herein, the gas outlets are slits that extend over at least part of the depth D of the guiding device.

According to some embodiments, which can be combined with any of the embodiments described herein, the guiding device includes a temperature adjusting system.

For instance, the temperature adjusting system may be a system of channels disposed in the guiding device. Typically, the channels are disposed close to the surface. The term “close to” typically relates to a distance of less than 5 cm, more typically less than 2.5 cm, and even more typically less than 1 cm between the surface oriented side of the channels and the surface. The channels are typically adapted for receiving a fluid. The fluid is a fluid suitable for cooling and/or heating and shall be called cooling fluid. In particular, for temperatures up to 100° C., even more particularly for temperature below room temperature, the cooling fluid is typically a water-glycol mixture. In other applications, in particular in those applications where the surface is heated, the cooling fluid is typically a heat transfer oil. The used cooling fluid is suitable for temperatures up to typically 400° C., even more typically up to 300° C. The heat transfer oil that is typically used in embodiments described herein is made on the basis of petroleum such as naphthene or paraffin. Alternatively, the heat transfer oil can be synthetic such as an isomer composite.

According to some embodiments, the gas emitted from the gas outlets is a gas having a heat conductivity of at least 0.01 W/mK, more typically of at least 0.05 W/mK, even more typically of at least 0.1 W/mK and even more typically of at least 0.15 W/mK.

The provision of the temperature adjusting system in combination with the multitude of gas outlets for generating a hover cushion allow for a temperature control of the web when the guiding device is in operation. In general, according to typical embodiments described herein, the guiding device is operated in vacuum. In vacuum, heat transfer can be accomplished by radiation only. However, through the hover cushion, i.e., the gas cushion, heat transfer can also take place by heat convection, increasing the effectiveness of the temperature control of the guiding device.

According to further embodiments, a coating apparatus is provided. The coating apparatus includes at least one coating tool and at least one guiding device according to embodiments described herein. The coating apparatus may include at least one further conventional guiding device making contact to the web, e.g. a conventional roller. Such additional conventional guiding devices may e.g. be employed where coating has not yet taken place or where only the back side has to be backed.

The coating apparatus typically includes a vacuum chamber, within which the at least one guiding device is placed. The coating apparatus may include a vacuum system including at least one vacuum pump for evacuating the vacuum chamber. Further, according to embodiments which can be combined with any of the embodiments described herein, the at least one coating tool for coating the web can be selected from the group including, e.g. coating tools for CVD, PVD, plasma enhanced chemical vapor deposition (PECVD) and sputtering. Coating may be performed by evaporating material or sputtering. In some embodiments, the coating material is selected from the group consisting of: amorphous silicon, protocrystalline silicon, nanocrystalline silicon, transparent and conductive oxide (TCO) layer material, indium tin oxide (ITO), zinc oxide (ZnO), aluminum-doped zinc oxide (ZAO), back contact layer material, e.g. aluminum (Al) and molybdenum (Mo).

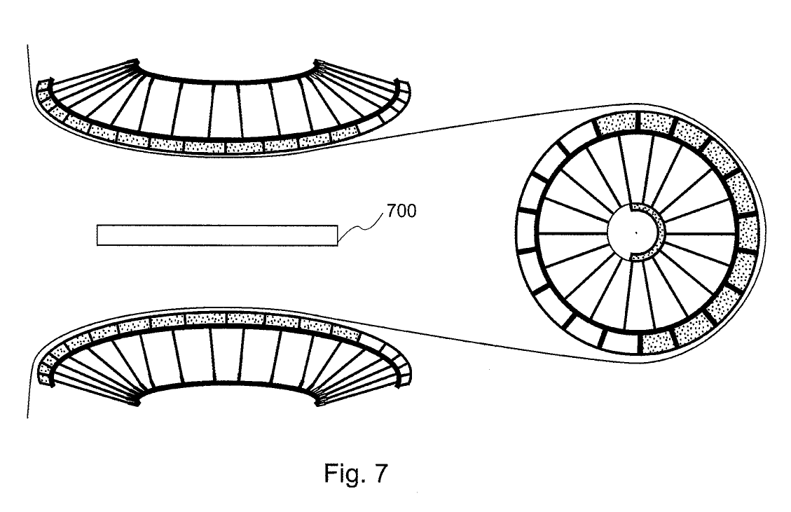

FIG. 7 illustrates an exemplary embodiment of a coating apparatus. The coating apparatus shown in FIG. 7 includes two guiding devices similar to those described with respect to FIGS. 5A-5C, and one guiding device similar to those described with respect to FIGS. 2A-2C. Further, the coating apparatus includes a coating tool 500.

During operation, the web may be guided over the first elliptic guiding device and its front side being coated by the coating tool 500. Then, the web is guided over the cylindrical guiding device changing the direction of movement by at least 180°, wherein the freshly coated front side of the web faces, but does not contact, the cylindrical guiding device. Afterwards, the web is guided over the second elliptical guiding device and its front side is coated again by coating tool 700.

Note that the dimensions such as the width of the elliptical guiding devices in FIG. 7, may e.g. be much larger than the diameter, i.e. the width, of the cylindrical guiding device. The figure is not necessarily true to scale neither as far as the components of individual guiding devices are concerned, nor as far as the scale of the individual guiding devices with respect to each other is concerned. The figure only schematically illustrates an arrangement of guiding devices in the coating apparatus.

By using at least one guiding device according to embodiments described herein in a web coating apparatus, the flexibility for arranging the components of the coating apparatus may be increased. Thereby, space may be saved. Components such as the elliptic guiding devices may be standard devices symmetric in built, but may be operated in an asymmetric way if web guiding permits or requires this. Generally, the flexibility in composing guiding devices is increased by the flexibility of the guiding devices themselves as described herein. The hover cushion, also called a hydrodynamic gas bearing, can be used to create a desired flow of sweep gas required to prevent stray dopant transfer to other parts of the coating apparatus. Together with the ability to selectively shut gas outlets not contributing to the hover cushion, this helps maintaining the necessary clean environment, in particular vacuum environment, for web coatings such as the deposition of electronic or optoelectronic semiconductor materials.

According to yet further embodiments, methods for contactless guiding of a web 1 in a web coating process are provided. The methods are typically carried out under vacuum conditions. A typical method includes moving the web 1 over a surface 110, typically a curved surface such as a rotationally symmetric or elliptic surface. Therein, the web is guided over a web guiding region of the surface 110. In the surface 110, gas outlets 111 are disposed which are adapted for giving off a gas to form a hover cushion between the curved surface and the web. The hover cushion may be provided such that the web 1 does not contact the surface 110.

According to embodiments described herein, the method includes selectively controlling a flow of the gas, in particular emitting the flow of the gas from the surface 110 through a first subgroup 112 of the gas outlets 111. Typically, emitting the flow of the gas from the surface 110 through the first subgroup 112 of the gas outlets includes emitting the flow in the web guiding region. The emitted flow of the gas generates the hover cushion between the surface 110 and the web.

According to typical embodiments, the method includes preventing the flow of the gas through a second subgroup 114 of the gas outlets. Preventing the flow of the gas through the second subgroup 114 of the gas outlets typically includes preventing the gas flow outside of the web guiding region.

Emitting, respectively preventing, the gas flow may be effected by opening, respectively closing, the first, respectively second, subgroup of gas outlets. In particular, opening the first subgroup 112 of the gas outlets may include connecting the first subgroup to a main gas feed 210. Therein, “connecting” in particular includes “bringing into fluid communication”. Similarly, closing the second subgroup 114 may include disconnecting the second subgroup 114 from the main gas feed 210.

According to some embodiments, the method includes distributing the gas such that the first subgroup 112 is provided with a flow of the gas and such that the second subgroup 114 is cut off from the flow of the gas.

In some embodiments, membership of the gas outlets to the first and second subgroups varies during operation. Typically, the surface 110 is rotated. Therein, gas outlets entering the web guiding area may become members of the first subgroup 112 of open gas outlets, and gas outlets leaving the web guiding area may become members of the second subgroup 114 of closed gas outlets. In some embodiments, the surface 110 is rotated with a surface velocity equal to the speed of the web. In this case, the web and the surface are said to be synchronized or to move alongside each other at least in the web guiding area. In such embodiments, a frequency of opening or closing any of the gas outlets 111 is proportional to the speed of the web.

For the surface of a roller, the surface velocity vₛ is connected to a rotation frequency f of the roller by the relation vₛ=W□f, wherein W is the diameter of the roller, which may be non-constant along the depth direction, e.g. for a concave-cylindrical drum. Generally, the surface speed vₛ, and hence the rotation frequency f, can be proportional to the web speed v_{w}. For instance, if the web speed doubles, so does the rotation frequency. For a cylindrical drum, the surface speed vₛ is typically chosen equal to the web speed v_{w}. According to embodiments which can be combined with any of the embodiments of a guiding device with a rotatable surface, the rotation frequency can be in the range from 0.02 1/min to 100 1/min. For CVD applications, the rotation frequency typically ranges from 0.3 1/min to 1.6 1/min, and for sputter applications from 1.25 1/min to 16 1/min.

In some embodiments of the methods described herein, the surface is heated or cooled. For example, the surface may be heated up to 400° C., more typically up to 300° C., whereas in other embodiments of the methods described herein, the surface is cooled down, in particular to temperatures of up to minus 30° C., e.g. up to minus 20° C. or minus 15° C.

In further embodiments, the method for coating the web includes testing whether the web is guided without contacting the guiding device. In particular, such testing whether the web is guided without contacting the guiding device may include biasing the web relative to the guiding device and detecting a short-circuit in case of a contact between the web and the guiding device. For testing, a metalized web can be used.

In yet further embodiments, methods for coating the web are provided. The methods for coating the web include any of the methods of guiding the web according to embodiments described herein. The methods for coating the web further include coating the web. In typical embodiments, the method includes evacuating the process environment, e.g. a process vacuum chamber.

Generally, according to even further embodiments, methods for contactless guiding of the web may include use of the functions of the guiding device according to any of the embodiments described herein.

The guiding device, the coating apparatus, the method for contact-free guiding of a web, and the method for coating a web can be particularly applicable in the production of thin-film solar cells or flexible displays. The thin films are typically deposited by CVD, in particular PECVD, from silane gas and hydrogen yielding to amorphous silicon or protocrystalline silicon or nanocrystalline silicon. The silicon layer is typically sandwiched by a back contact such as a metal and a transparent and conductive oxide (TCO) layer.

A typical method for producing a thin-film solar cell comprises depositing a back contact on the web, depositing an absorbing layer such as amorphous silicon or the like, and depositing a TCO layer. Each depositing can comprise several sub steps. For instance, the deposition of amorphous silicon has to follow a predetermined sequence of positively doped, intrinsic (non-doped), and negatively doped silicon layers. Dependent on the design of the solar cell, the solar cell may comprise several negatively doped layers and/or several positively doped layers and/or several intrinsic layers. Embodiments described herein can be particularly advantageous in the production of thin-film solar cells since a contact of the coated side of the web with any guiding means has to be prevented in order not to damage any deposited layer.

It is further typical in the production of a solar cell to coat the TCO layer with a protective layer. The typical coating process for the back contact is sputtering. The typical coating process for coating the absorbing layer that is typically made of amorphous silicon is a CVD or PECVD process. The typical coating process for coating the TCO layer is sputtering. In general, CVD is typically accomplished under a pressure in the range of between 1 mbar and 100 mbar. Sputtering is typically accomplished under a pressure of between 10⁻² mbar and 10⁻⁴ mbar.

While the foregoing is directed to embodiments of the invention, other and further embodiments of the invention may be devised without departing from the basic scope thereof, and the scope thereof is determined by the claims that follow.

1. A guiding device for contactless guiding of a web in a web coating process application under vacuum conditions, the guiding device comprising:
a curved surface for facing the web;
a group of gas outlets disposed in the curved surface and adapted for giving off a gas flow to form a hover cushion between the curved surface and the web; and
a gas distribution system for selectively providing the gas flow to a first subgroup of the gas outlets and for selectively preventing the gas from flowing to a second subgroup of the gas outlets.

2. The guiding device according to according to claim 1, wherein the curved surface comprises a web guiding region, and wherein the first subgroup of the gas outlets comprises at least one gas outlet in the web guiding region and the second subgroup of gas outlets comprises at least one gas outlet outside of the web guiding region.

3. The guiding device according to according to claim 1, wherein a membership of the individual gas outlets to either the first subgroup or the second subgroup is variable.

4. The guiding device according to according to claim 1, wherein the guiding device is a roller having an axis, and the curved surface is rotationally symmetric with respect to the axis.

5. The guiding device according to claim 1, wherein the guiding device is a drum having an axis, the curved surface being the surface of the drum and having a shape selected from the group of shapes consisting of a cylindrical shape and a concave-cylindrical shape.

6. The guiding device according to claim 1, wherein the curved surface is rotatable around an axis.

7. The guiding device according to claim 6, wherein the curved surface is adapted for rotating with a surface velocity equal to a guiding velocity of the web such that any part of the curved surface overlapped by the web is substantially stationary with respect to the web.

8. The guiding device according to claim 1, wherein the gas distribution system comprises:
a main gas feed; and
individual gas outlet feeds in fluid communication with the gas outlets, the individual gas outlet feeds being adapted for selectively connecting the main gas feed to the first subgroup of the gas outlets and for selectively disconnecting the main gas feed from the second subgroup of the gas outlets.

9. The guiding device according to claim 8, wherein the main gas feed is non-rotatable, the individual gas outlet feeds are rotatable together with the curved surface, and the individual gas outlet feeds are adapted to selectively connect to or disconnect from the main gas feed depending on their relative position with respect to the main gas feed upon rotation.

10. The guiding device according to claim 1, wherein the gas distribution system comprises:
a multitude of sector chambers, wherein each sector chamber includes at least one gas inlet connectable to a gas feed, and wherein each sector chamber is in fluid communication with a number of gas outlets that is greater than the number of gas inlets of the sector chamber.

11. The guiding device according to claim 1, wherein the gas distribution system is a star distributor for providing the gas flow into a sector angle of the guiding device.

12. The guiding device according to claim 11, wherein the sector angle is adjustable.

13. The guiding device according to claim 1, wherein the gas outlets are disposed closer together in a center region of the curved surface than in an edge region of the curved surface.

14. The guiding device according to claim 1, wherein the gas distribution system further comprises:
a valve system for selectively providing the gas flow to the first subgroup of the gas outlets and for selectively preventing the gas from flowing to the second subgroup of the gas outlets.

15. The guiding device according to claim 1, further comprising:
a temperature adjustment system for adjusting the temperature of the guiding device.

16. An apparatus for coating a web comprising
a coating tool for coating the web, and
a guiding device for contactless guiding of a web in a web coating process application under vacuum conditions, the guiding device comprising:
i. a curved surface for facing the web;
ii. a group of gas outlets disposed in the curved surface and adapted for giving off a gas flow to form a hover cushion between the curved surface and the web; and
iii. a gas distribution system for selectively providing the gas flow to a first subgroup of the gas outlets and for selectively preventing the gas from flowing to a second subgroup of the gas outlets.

17. A method for contactless guiding of a web in a web coating process under vacuum conditions, the method comprising:
moving the web over a curved surface in a web guiding region of the curved surface, wherein gas outlets are disposed in the curved surface which are adapted for giving off a gas to form a hover cushion between the curved surface and the web;
emitting a flow of the gas from the curved surface through a first subgroup of the gas outlets in the web guiding region for generating the hover cushion between the curved surface and the web; and
preventing the gas from flowing through a second subgroup of the gas outlets outside of the web guiding region.

18. The method according to claim 17, further comprising:
varying a membership of the gas outlets to the first and second subgroups, preferably by rotating the curved surface.

19. The method according to claim 17, further comprising:
moving the curved surface substantially alongside the web in the web guiding region, wherein the web guiding velocity and the surface velocity are synchronized.

20. The method according to claim 17, wherein the curved surface is rotationally symmetric with respect to an axis, the method further comprising:
rotating the rotationally symmetric surface around the axis with a rotation frequency that is proportional to the speed of moving the web.

21. The method according to claim 17, wherein emitting the flow of the gas comprises connecting the first subgroup of the gas outlets to a main gas feed for providing the flow of the gas, and wherein preventing the flow of the gas comprises disconnecting the second subgroup of the gas outlets from the main gas feed.

22. The method according to claim 17, wherein the gas is selected from the group consisting of inert gases, nitrogen, argon, hydrogen, and silane.

23. The method according to claim 17, wherein emitting the flow of the gas comprises emitting the flow of the gas at a rate from 0.1 to 30 slmp.

24. The method according to claim 17, wherein emitting the flow of the gas comprises emitting the flow of the gas at a higher rate in a center region of the curved surface than in an edge region of the curved surface.

25. A method for coating a web comprising:
coating the web via a method for contactless guiding of the web under vacuum conditions, the method for contactless guiding comprising:
moving the web over a curved surface in a web guiding region of the curved surface, wherein gas outlets are disposed in the curved surface which are adapted for giving off a gas to form a hover cushion between the curved surface and the web;
emitting a flow of the gas from the curved surface through a first subgroup of the gas outlets in the web guiding region for generating the hover cushion between the curved surface and the web; and
preventing the gas from flowing through a second subgroup of the gas outlets outside of the web guiding region.
